(19) United States
(12) Patent Application Publication
(10) Pub. No.: US 2004/0136169 A1
(43) Pub. Date: Jul. 15, 2004

(54) Printed circuit board, a buildup substrate, a method of manufacturing printed circuit board, and an electronic device

(76) Inventors: Shigeru Morimoto, Osaka (JP); Hisashi Adachi, Osaka (JP); Toshifumi Nakatani, Osaka (JP); Koji Takinami, Osaka (JP)

Correspondence Address: RATNERPRESTIA, P O BOX 980, VALLEY FORGE, PA, 19482-0980, US

(21) Appl. No.: 10/676,569

(22) Filed: Sep. 30, 2003

(30) Foreign Application Priority Data
Sep. 30, 2002 (JP) 2002-287850

(51) Int. Cl. H05K 7/06

(52) U.S. Cl. 361/780; 174/262

(57) ABSTRACT

To provide a printed circuit board, a buildup substrate and a method of manufacturing the printed circuit board capable of curbing a transmission loss thereof at a desired frequency.

A printed circuit board having a multilayer substrate, a via hole penetrating the multilayer substrate, a surface wiring wired on the surface of the multilayer substrate and connected to an end which is one end of the via hole, at least one inner layer wiring formed inside the multilayer substrate and connected to a portion other than upper and lower ends of a conductive part of the via hole, and a current-carrying element connected to an end having no surface wiring connected thereto on an opposite side to the end, and wherein the current-carrying element has an electrical length by which a value of an impedance at a predetermined frequency on seeing the current-carrying element side from a connection point between the inner layer wiring and the via hole closest to the end is larger than a value of the impedance on seeing the end from the connection point in the case where the current-carrying element is nonexistent.

### BACKGROUND OF THE INVENTION

1. Field of the Invention

The present invention relates to a printed circuit board, a method of manufacturing it, a buildup substrate utilizing the printed circuit board, and an electronic device utilizing the printed circuit board.

2. Related Art of the Invention

Concerning information equipment in recent years, there is a necessity to transmit a high-speed signal of GHz or so on a multilayer substrate. For instance, there is a multilayer printed circuit board as a prior art, which curbs voltage variation between a power supply and a ground and efficiently curbs malfunction of devices due to radiation of an unnecessary electromagnetic wave and intrusion of an external electromagnetic field (refer to Japanese Patent Laid-Open No. 10-190237. The disclosure of the above document is incorporated herein by reference in its entirety.) As for such a multilayer substrate, there is an IVH (InnerVia Hole) substrate. While the IVH substrate has an advantage that it can form a via hole only between desired layers to effectively exploit the space, it has a drawback that it is time-consuming for production and expensive.

Thus, a glass epoxy resin is often used as a material for an inexpensive multilayer substrate. To connect lines of a surface and an inner layer of the multilayer substrate using the glass epoxy resin as a material, the via hole penetrating the multilayer substrate is generally used. FIG. 16 shows an appearance of a via hole 1003 penetrating such a multilayer substrate 1001 formed on the multilayer substrate 1001. The inside of the via hole 1003 is covered with a conductive layer (not shown). A surface wiring 1002 is mounted on the surface on the upper side of the multilayer substrate 1001 shown in FIG. 16, and a part of the surface wiring 1002 is connected to an end 1006 which is one end of the via hole 1003. An inner layer wiring 1004 is mounted between the layers inside the multilayer substrate 1001, and is connected to a connection point 1008 which is a portion other than the upper and lower ends of the conductive portion of the via hole 1003. And nothing is connected to the portion from the connection point 1008 to an end 1007 opposed to an end 1006 of the conductive portion of the via hole 1003.

However, as to a structure in which the via hole penetrating through the lines on a surface to a rear surface of a multilayer substrate using a glass epoxy resin is formed, an unnecessary end of the via hole forms a resonator, and a power loss occurs at a desired frequency due to resonation of this resonator.

In the example shown in FIG. 16, the portion from the end 1006 to the connection point 1008 of the conductive portion of a via hole 1003 is the necessary portion effectively operating to convey a signal conveyed to a surface wiring 1002 to an inner layer wiring 1004. Of the conductive portion of the via hole 1003, however, the portion from a connection point 1008 to an end 1007 is an unnecessary portion 1005 which is essentially not effectively operating to convey the signal.

The multilayer substrate shown in FIG. 16 will be as shown in FIG. 18 if represented by an equivalent circuit. The surface wiring 1002 is represented by a line D1. The inner layer wiring 1004 is represented by a line D3. Of the conductive portion of the via hole 1003, the necessary portion is represented by a line D2 and the unnecessary portion 1005 is represented by a line D4.

As described above, the unnecessary portion 1005 of the via hole 1003 forms a resonator by an open stub, and causes resonation. FIG. 17 shows a relationship between change in electrical length of the unnecessary portion 1005 and an attenuation of the signal conveyed from the surface wiring 1002 to the inner layer wiring 1004. As shown in this drawing, the attenuation becomes the largest when the electrical length of the unnecessary portion 1005 becomes the electrical length corresponding to ¼ of a wavelength thereof at a desired frequency.

An object of the present invention is to provide a printed circuit board, a buildup substrate and a method of manufacturing the printed circuit board capable of curbing a transmission loss thereof at the desired frequency in consideration of the problem.

### SUMMARY OF THE INVENTION

According to the present invention, it is possible to provide the printed circuit board, buildup substrate and method of manufacturing the printed circuit board capable of curbing the transmission loss thereof at the desired frequency.

The 1^{st} aspect of the present invention is a printed circuit board having:

a multilayer substrate;

a via hole penetrating said multilayer substrate;

a surface wiring wired on the surface of said multilayer substrate and connected to a first end which is one end of said via hole;

at least one inner layer wiring formed inside said multilayer substrate and connected to a portion other than upper and lower ends of a conductive part of said via hole; and

a current-carrying element connected to a second end having no said surface wiring connected thereto on an opposite side to said first end of the conductive part of said via hole; and wherein:

said current-carrying element has an electrical length by which a value of an impedance at a predetermined frequency is larger than a predetermined value on seeing said current-carrying element side from a first connection point closest to said second end, of the connection points between said inner layer wiring and the conductive part of said via hole; and

said predetermined value is the value of the impedance at the predetermined frequency on seeing said second end side from said first connection point in the case where said current-carrying element does not exist.

The 2^{nd} aspect of the present invention is the printed circuit board according to the 1^{st} aspect of the present invention, wherein the total of the electrical length from said first connection point to said second end and the electrical length of said current-carrying element is substantially n/2 times (n is a natural number) a wavelength corresponding to said predetermined frequency, and the end of said current-carrying element is open.

The 3^{rd} aspect of the present invention is the printed circuit board according to the 1^{st} aspect of the present invention, wherein the total of the electrical length from said first connection point to said second end and the electrical length of said current-carrying element is substantially (2n−1)/4 times (n is a natural number) a wavelength corresponding to said predetermined frequency, and the end of said current-carrying element is grounded.

The 4^{th} aspect of the present invention is the printed circuit board according to any one of the 1^{st} to the 3^{rd} aspects of the present invention, wherein a part of said current-carrying element is formed by a chip inductor.

The 5^{th} aspect of the present invention is the printed circuit board according to any one of the 1^{st} to the 3^{rd} aspects of the present invention, wherein a part of said current-carrying element is formed by at least one via hole.

The 6^{th} aspect of the present invention is the printed circuit board according to any one of the 1^{st} to the 3^{rd} aspects of the present invention, wherein a shape of said current-carrying element is substantially a sector.

The 7^{th} aspect of the present invention is the printed circuit board according to the 1^{st} aspect of the present invention, wherein said current-carrying element is formed between predetermined layers between said first connection point and said second end and is connected to the conductive part of said via hole instead of being connected to said second end.

The 8^{th} aspect of the present invention is the printed circuit board according to the 1^{st} aspect of the present invention, further having another via hole penetrating said multilayer substrate different from said via hole; and wherein:

said surface wiring is a differential signal line, and one end of said differential signal line is connected to the first end of said via hole and the other end of said differential signal line is connected to one end of said other via hole;

at least one inner layer wiring is connected to a portion other than upper and lower ends of the conductive part of said other via hole;

a current-carrying element other than said current-carrying element is connected to the other end of said other via hole;

of the conductive part of said via hole, the total of the electrical length from said first connection point to said second end and the electrical length of said current-carrying element is substantially (2n−1)/4 times (n is a natural number) a wavelength corresponding to said predetermined frequency;

of the conductive part of said other via hole, the total of the electrical length from the connection point closest to said other end to said other end of the connection points to said inner layer wiring and the electrical length of said other current-carrying element is substantially (2n−1)/4 times (n is a natural number) the wavelength corresponding to said predetermined frequency; and

the end of said current-carrying element and the end of said other current-carrying element are mutually connected.

The 9^{th} aspect of the present invention is a printed circuit board having:

a multilayer substrate;

a via hole penetrating said multilayer substrate;

a surface wiring wired on the surface of said multilayer substrate and connected to a first end which is one end of said via hole;

at least one inner layer wiring formed inside said multilayer substrate and connected to a portion other than upper and lower ends of a conductive part of said via hole; and

a series circuit of a resistor and a capacitor, and wherein:

said series circuit is connected, of the conductive part of said via hole, between a second end having no said surface wiring connected thereto on an opposite side to said first end and a first connection point closest to said second end, of the connection points between said inner layer wiring and the conductive part of said via hole.

The 10^{th} aspect of the present invention is the printed circuit board according to the 9^{th} aspect of the present invention, wherein said resistor is a chip resistor connected to said second end;

said capacitor is formed by said inner layer wiring or inner layer pattern and a land as electrodes and a part of said multilayer substrate as a dielectric; and

said inner layer wiring or inner layer pattern is connected to said first connection point, said land is formed on a surface on which said second end exists and is connected to said chip resistor, and a part of said multilayer substrate is formed by being sandwiched between said inner layer wiring or inner layer pattern and said land.

The 11^{th} aspect of the present invention is a buildup substrate having the printed circuit board according to the 1^{st} aspect of the present invention and a substrate layer of at least one layer formed on said printed circuit board.

The 12^{th} aspect of the present invention is a method of manufacturing a printed circuit board having:

a step of connecting a current-carrying element to a second end having no surface wiring connected thereto on an opposite side to a first end of a via hole penetrating a multilayer substrate and having a surface wiring connected to said first end of a conductive part thereof; and

a step of determining an electrical length of said current-carrying element so that a value of an impedance at a predetermined frequency on seeing said current-carrying element side from a first connection point closest to said second end, of connection points between at least one inner layer wiring connected to a portion other than said first end and said second end of the conductive part of said via hole and formed inside said multilayer substrate and the conductive part of said via hole, is higher than a predetermined value, and wherein:

said predetermined value is the value of the impedance at said predetermined frequency on seeing said second end side from said first connection point in the case where said current-carrying element does not exist.

The 13^{th} aspect of the present invention is a method of manufacturing a printed circuit board, wherein a series circuit of a resistance and a capacitor is connected between a second end having no surface wiring connected thereto on an opposite side to a first end of a via hole penetrating a multilayer substrate and having a surface wiring connected to said first end of a conductive part thereof and a first connection point closest to said second end, of connection points between at least one inner layer wiring connected to a portion other than said first end and said second end of the conductive parts of said via hole and formed inside said multilayer substrate and the conductive part of said via hole.

The 14^{th} aspect of the present invention is an electronic device having the printed circuit board according to the 1^{st} aspect of the present invention and electronic components mounted on the surface of or inside said printed circuit board.

### BRIEF DESCRIPTION OF THE DRAWINGS

FIG. 1(a) is a cross-section of a printed circuit board according to a first embodiment of the present invention;

FIG. 1(b) is a rear surface plan view of the printed circuit board according to the first embodiment of the present invention;

FIG. 1(c) is a rear surface plan view of the printed circuit board according to the first embodiment of the present invention;

FIG. 2(a) is a diagram showing a voltage characteristic of an open stub type of the printed circuit board according to the first embodiment of the present invention;

FIG. 2(b) is a diagram describing a position of the open stub type of the printed circuit board according to the first embodiment of the present invention;

FIG. 2(c) is a diagram showing an impedance characteristic of the open stub type of the printed circuit board according to the first embodiment of the present invention;

FIG. 3 is a circuit connection diagram showing an equivalent circuit of the printed circuit board according to the embodiment of the present invention;

FIG. 4(a) is a diagram showing a voltage characteristic of a short stub type of the printed circuit board according to the first embodiment of the present invention;

FIG. 4(b) is a diagram describing a position of the short stub type of the printed circuit board according to the first embodiment of the present invention;

FIG. 4(c) is a diagram showing the impedance characteristic of the short stub type of the printed circuit board according to the first embodiment of the present invention;

FIG. 5(a) is a cross-section showing an alternative example of the printed circuit board according to the first embodiment of the present invention;

FIG. 5(b) is a rear surface plan view showing the alternative example of the printed circuit board according to the first embodiment of the present invention;

FIG. 6(a) is a cross-section showing the alternative example of the printed circuit board according to the first embodiment of the present invention;

FIG. 6(b) is a rear surface plan view showing the alternative example of the printed circuit board according to the first embodiment of the present invention;

FIG. 7 is a rear surface plan view showing the alternative example of the printed circuit board according to the first embodiment of the present invention;

FIG. 8(a) is a cross-section view showing the alternative example of the printed circuit board according to the first embodiment of the present invention;

FIG. 8(b) is a cross-section view showing the alternative example of the printed circuit board according to the first embodiment of the present invention;

FIG. 9 is a cross-section view of a buildup substrate formed as the alternative example of the printed circuit board according to the first embodiment of the present invention;

FIG. 10(a) is an internal perspective view of the printed circuit board when a differential signal is used in the case where the short stub type is used as the alternative example of the printed circuit board according to the first embodiment of the present invention;

FIG. 10(b) is a rear surface plan view of the printed circuit board when the differential signal is used in the case where the short stub type is used as the alternative example of the printed circuit board according to the first embodiment of the present invention;

FIG. 11 is an internal perspective view of the printed circuit board according to a second embodiment of the present invention;

FIG. 12 is a circuit connection diagram showing an equivalent circuit of the printed circuit board according to the second embodiment of the present invention;

FIG. 13(a) is a rear surface plan view of the printed circuit board according to the second embodiment of the present invention;

FIG. 13(b) is a rear surface plan view of the alternative example of the printed circuit board according to the second embodiment of the present invention;

FIG. 14(a) is a diagram showing a frequency characteristic of an attenuation of the printed circuit board of a prior art;

FIG. 14(b) is a diagram showing the frequency characteristic of the attenuation of the printed circuit board according to the first embodiment of the present invention;

FIG. 15(a) is a diagram showing the frequency characteristic of the attenuation of the printed circuit board of the prior art;

FIG. 15(b) is a diagram showing the frequency characteristic of the attenuation of the printed circuit board according to the second embodiment of the present invention;

FIG. 16 is a cross-section view of the printed circuit board of the prior art;

FIG. 17 is a diagram showing the characteristic of the printed circuit board of the prior art; and

FIG. 18 is a circuit connection diagram showing the equivalent circuit of the printed circuit board of the prior art.

### DESIGNATION OF REFERENCE NUMERALS

1 Multilayer substrate

2 Surface wiring

3, 18 Via holes

4, 9 Inner layer wirings

5 Second portion

6, 7 Ends

8, 16 Connection points

9 Current-carrying element

14 Ground electrode

15 Chip inductor

17 Substrate

20 Connection portion

21 Inner layer pattern

22 Land pattern

23 Chip resistor

24 Capacitor

### PREFERRED EMBODIMENTS OF THE INVENTION

(First Embodiment)

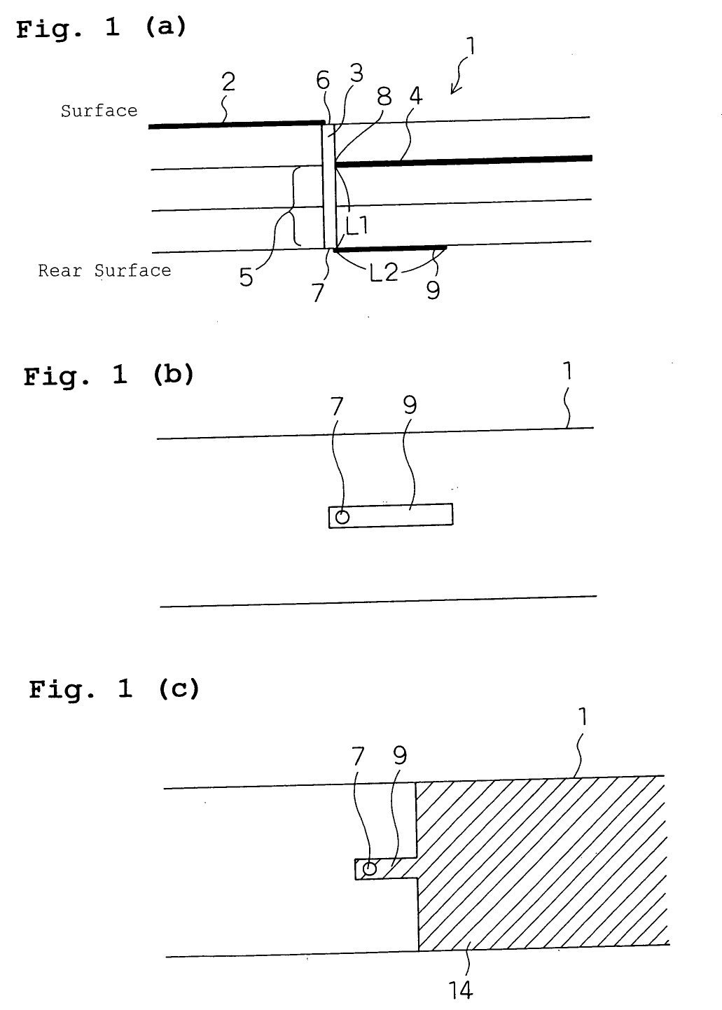

FIG. 1 shows a sectional view of a printed circuit board according to a first embodiment of the present invention.

First, a configuration of the printed circuit board according to the first embodiment will be described. The printed circuit board shown in FIG. 1 uses a glass epoxy substrate as a multilayer substrate 1, and a via hole 3 penetrating the multilayer substrate 1 is formed thereon. The inner layer of the via hole 3 is covered with a conductive layer (not shown). A surface wiring 2 is mounted on the surface on the upper side of the multilayer substrate 1 shown in FIG. 1, and a part of the surface wiring 2 is connected to an end 6 which is one end of the via hole 3 and an example of a first end of the present invention. An inner layer wiring 4 is mounted between the layers inside the multilayer substrate 1, and is connected to a connection point 8 which is a portion other than the upper and lower ends of the conductive portion of the via hole 3 and an example of a first connection point of the present invention.

Of the conductive portion of the via hole 3, a current-carrying element 9 of an electrical length L2 is connected to an end 7 which is an example of a second end of the present invention having no surface wiring 2 connected thereto on an opposite side (on a rear surface shown in FIG. 1) to the end 6, and is placed along the rear surface of the multilayer substrate 1. FIG. 1(b) shows a plan view seeing the printed circuit board shown in FIG. 1(a) from the rear surface. Thus, the current-carrying element 9 is mounted on the rear surface of the printed circuit board with its ends connected to nothing.

Here, of the conductive portion of the via hole 3, the portion from the end 6 to the connection point 8 is defined as a first portion originally necessary for operation of the via hole 3, and the portion from the connection point 8 to the end 7 is defined as a second portion essentially unnecessary for the operation of the via hole 3. In FIG. 1(a) and so on, reference numeral 5 denotes the second portion. Let the electrical length of the second portion is L1, the electrical length L2 of the current-carrying element 9 is determined to be as follows for a wavelength λ corresponding to a desired frequency.

L1+L2=nλ/2 (n is a natural number) [Formula 1]

Next, the operation of the printed circuit board according to this embodiment will be described. Before the description thereof, a principle of operation of an open stub will be described.

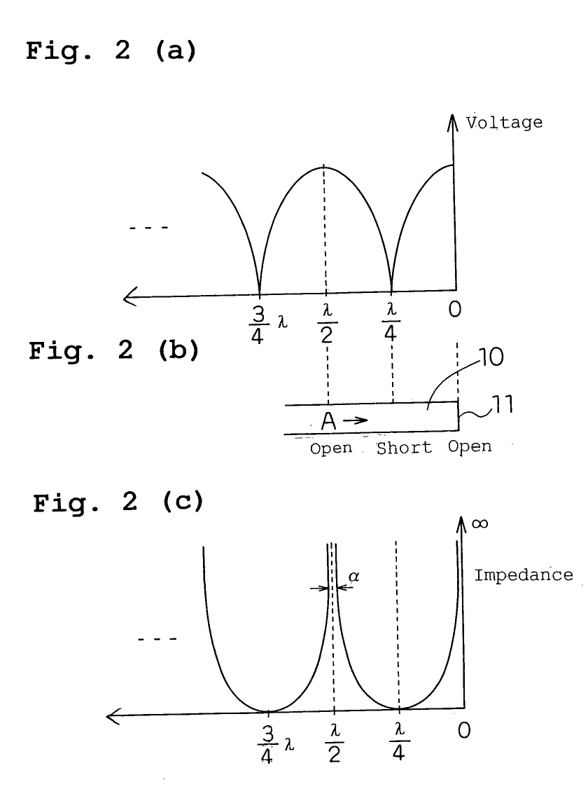

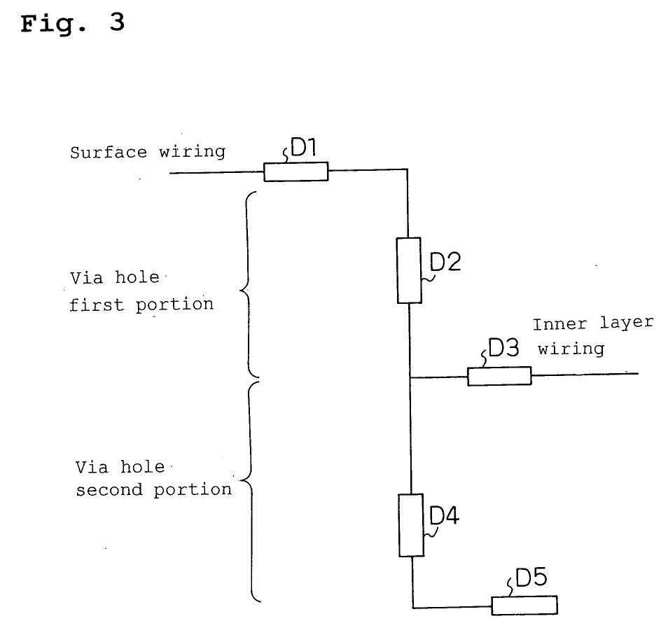

FIGS. 2 are diagrams explaining the principle of operation of an open stub 10. FIG. 2(c) is a diagram showing an impedance on seeing an open end 11 side from each point in FIG. 2(b) at a signal of a predetermined wavelength λ. In the open stub 10, the impedance on seeing the open end 11 side from a point A distant by λ/2 from the open end 11 is substantially infinite (maximum). As shown in FIG. 2(a), voltage of the signal at the point A also becomes maximum. To be more specific, in the open stub 10, it is the same state as being open at the point A distant by λ/2 from the open end 11. It is also in the open state at a point distant by nλ/2 (n is a natural number of 2 or more) from the open end.

Therefore, if the via hole 3 and current-carrying element 9 are regarded as the open stubs, and in the case where the condition of (Formula 1) is satisfied, the impedance at a predetermined frequency on seeing the end 7 from the connection point 8 is infinite. Thus, as long as the condition of (Formula 1) is satisfied at the predetermined frequency, the via hole 3 only connects the surface wiring 2 to the inner layer wiring 4 at the predetermined frequency (1/λ) and the second portion 5 is nonexistent in fact so that an electrical signal of the wavelength λ is not influenced by the second portion 5 and the current-carrying element 9.

FIG. 3 shows an equivalent circuit of the printed circuit board shown in FIG. 1. The circuit shown in FIG. 3 is constituted by connecting a line D5 to the end of a line D4. In the circuit shown in FIG. 3, the electrical signal of the wavelength is not influenced by D4 and D5 if the above (Formula 1) is satisfied.

As described above, as for the printed circuit board according to this embodiment, it is possible, even by using the glass epoxy substrate, to implement the printed circuit board having a transmission loss due to resonation of the second portion 5 of the via hole 3 curbed at the desired frequency.

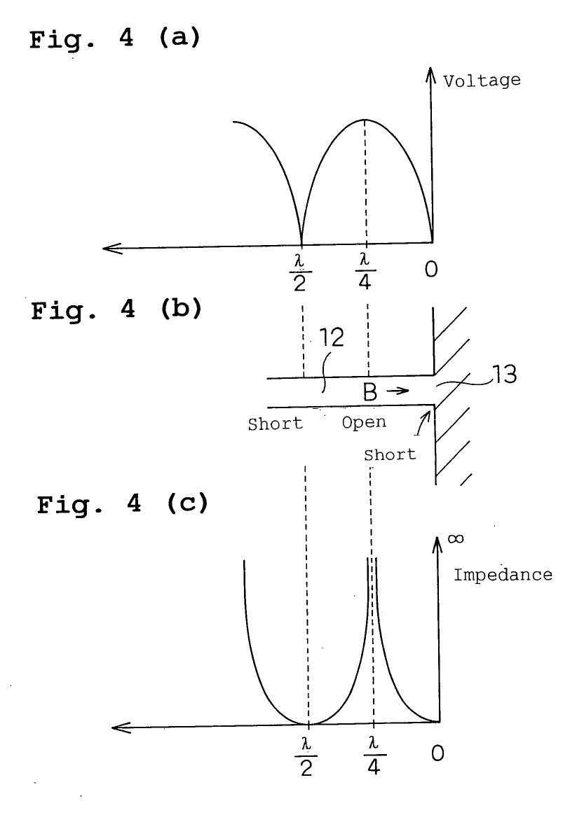

While the above was described by taking an example of the case where the second portion 5 of the via hole 3 and the current-carrying element 9 operate as the open stubs, there are also the thinkable cases where the second portion 5 of the via hole 3 and the current-carrying element 9 operate as short stubs. FIGS. 4 are diagrams explaining the principle of operation of a short stub 12. FIG. 4(c) is a diagram showing the impedance on seeing a short end 13 side from each point in FIG. 4(b) at the signal of the predetermined wavelength λ. For instance, at a point B distant by λ/4 from the short end 13, the impedance on seeing the short end 13 side from the point B is substantially infinite (FIG. 4(c)) . As shown in FIG. 4(a), the voltage of the signal at the point B becomes maximum. To be more specific, it is the same state as being open at the point distant by λ/4 from the short end 13 at the predetermined frequency (1/λ). It is also in the open state at the point distant by (2n−1)/4 (n is a natural number of 2 or more) from the short end 13 at the predetermined frequency.

Therefore, if the via hole 3 and current-carrying element 9 are regarded as the short stubs, and in the case where the following condition is satisfied, the impedance at the predetermined frequency on seeing the end 7 side from the connection point 8 is infinite.

L1+L2=(2n−1)/4 (n is a natural number) [Formula 2]

To be more specific, in the case where the electrical length of the current-carrying element 9 is determined so that the impedance at the predetermined frequency corresponding to the wavelength λ is maximum on seeing the current-carrying element 9 side from the connection point 8, the via hole 3 only connects the surface wiring 2 to the inner layer wiring 4 for the electrical signal of the predetermined wavelength λ, and it is not influenced by the portion from the connection point 8 to the end 7 of the conductive portion of the via hole 3 and current-carrying element 9. FIG. 1(c) shows a plan view seeing the printed circuit board from the rear surface in the case where the second portion 5 of the via hole 3 and the current-carrying element 9 operate as the short stubs. Thus, the current-carrying element 9 is placed on the rear surface of the printed circuit board in a state in which the end thereof is connected to a ground electrode 14 which is an example of an earth electrode of the present invention.

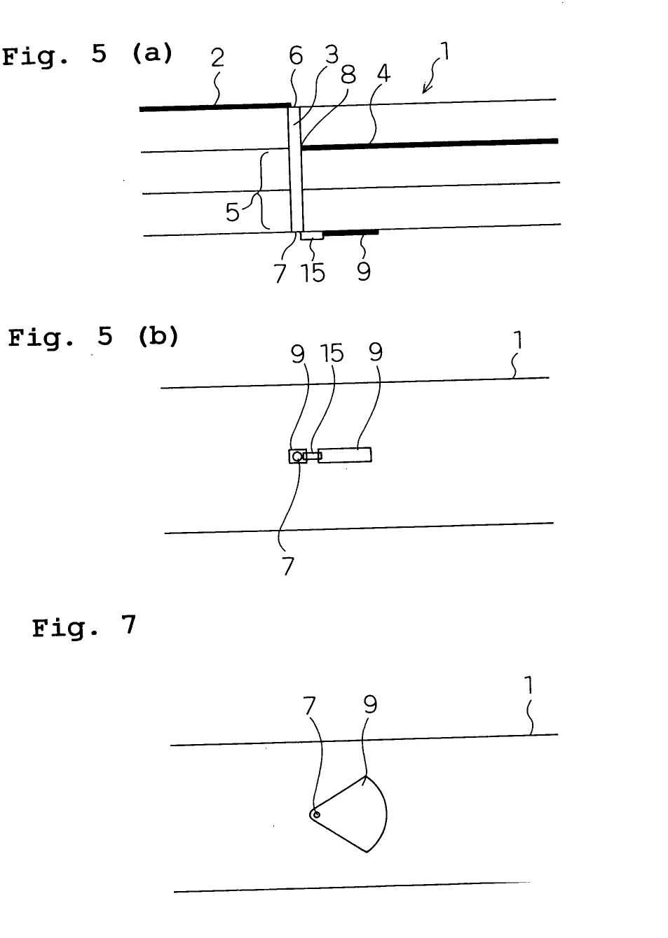

As for the above description, a part of the current-carrying element 9 may be constituted by a chip inductor. In that case, it is possible to decrease the entire length of the current-carrying element 9 placed on the rear surface of the printed circuit board according to this embodiment. FIG. 5(a) shows a cross-section of the printed circuit board according to this embodiment in the case where a chip inductor 15 is placed, and FIG. 5(b) is a plan view from the rear surface thereof. Thus, if the electrical length of the entire current-carrying element 9 is L2, it is possible to decrease physical length of the current-carrying element 9 while reducing the transmission loss as above so as to reduce a wiring area on the rear surface of the printed circuit board according to this embodiment. Even in the case where the current-carrying element 9 is the short stub, it is possible to decrease the physical length of the current-carrying element 9 as in the case of the open stub by using a chip inductor 15.

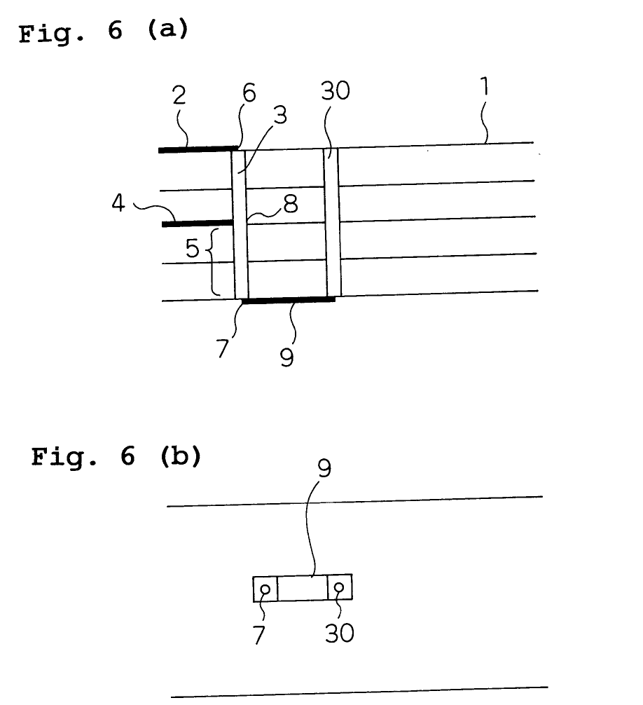

It is also possible to constitute a part of the current-carrying element 9 by a via hole 30. In that case, it is possible to decrease the length of a portion placed on the rear surface of the printed circuit board of the current-carrying element 9 according to this embodiment. FIG. 6(a) shows the cross-section of the printed circuit board according to this embodiment in such a case, and FIG. 6(b) is a plan view from the rear surface thereof. If the electrical length of the current-carrying element 9 including the via hole 30 is L2, it is possible to reduce the wiring area for the current-carrying element 9 on the rear surface of the printed circuit board according to this embodiment while reducing the transmission loss as above. FIGS. 6A and 6B show the case of one via hole 30. However, a portion of the current-carrying element 9 may be constituted by a plurality of via holes. In such a case, it is possible to further reduce the wiring area for the current-carrying element 9 on the rear surface of the printed circuit board according to this embodiment.

The current-carrying element 9 is not limited to a line-like shape but may be a sector. FIG. 7 shows a plan view from the rear surface of the printed circuit board according to this embodiment in the case where the current-carrying element 9 is formed as the sector. In this case, it is formed so that the radius of the sectorial current-carrying element 9 (that is, a distance from the connection with the via hole 3 to the sectorial arc) becomes L2. Thus, it is possible, by rendering the shape of the current-carrying element 9 substantially sectorial, to expand a frequency range α exceeding a predetermined impedance around λ/2 shown in FIG. 2(c). To be more specific, it is possible to implement the printed circuit board according to this embodiment in a wider frequency range centering on λ/2.

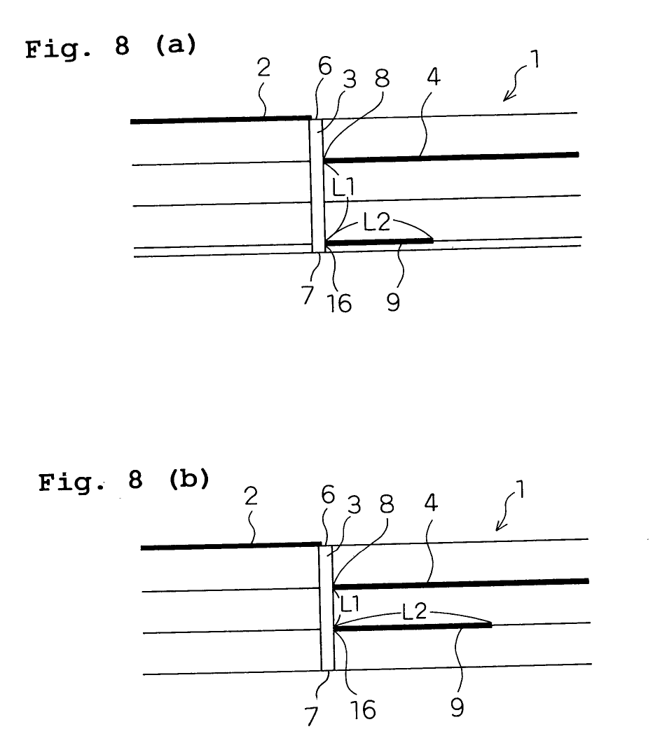

According to the above description, the current-carrying element 9 is placed along the surface on the rear surface of the multilayer substrate 1. However, the current-carrying element 9 may be placed in the neighborhood of the rear surface of the multilayer substrate 1. FIG. 8(a) shows across-section of the printed circuit board in the case where the current-carrying element 9 is placed not along the surface on the rear surface of the multilayer substrate 1 but between the layers in the neighborhood of the rear surface. In this case, the current-carrying element 9 is connected to a connection point 16 close to the end 7 of the conductive portion of the via hole 3. And the total of an electrical length L1 from the connection point 8 to the connection point 16 of the conductive portion of the via hole 3 and the electrical length L2 of the current-carrying element 9 is formed so as to satisfy (Formula 1) in the case of the open stubs and satisfy (Formula 2) in the case of the short stubs. Thus, it is possible to obtain the same effect as described above.

Furthermore, the current-carrying element 9 may be connected between the connection point 8 and the end 7 instead of being placed in the neighborhood of the rear surface of the multilayer substrate 1 (refer to FIG. 8(b)) . To be more specific, the current-carrying element 9 may be formed between predetermined layers from the connection point 8 to the end 7 and connected to the conductive portion of the via hole 3 instead of being connected to the end 7. In that case, it is also possible to obtain the same effect as described above.

According to the above description, the current-carrying element 9 is determined so that the total of its electrical length (L2) and the electrical length (L1) of the second portion 5 of the via hole 3 satisfy the condition of (Formula 1) or (Formula 2). To be more specific, the electrical length of the current-carrying element 9 is determined so that the impedance at the predetermined frequency corresponding to the wavelength λ is maximum on seeing the current-carrying element 9 side from the connection point 8. However, the electrical length L2 may be determined so that the value of the impedance at the predetermined frequency on seeing the current-carrying element 9 side from the connection point 8 becomes larger than the predetermined value.

Furthermore, the predetermined value in that case may be the impedance on seeing the end 7 side from the connection point 8 in the case where the current-carrying element 9 is nonexistent. Even in such a case, it is possible to obtain the same effect as described above.

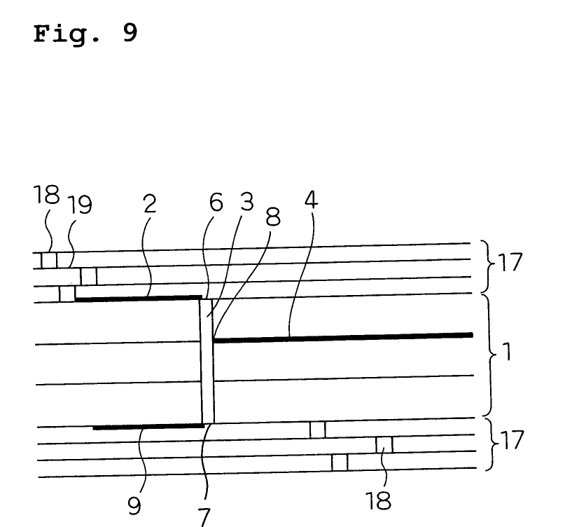

There is also a thinkable case where a substrate 17 formed by at least one resin layer is formed on the surface or the rear surface of the printed circuit board described above so as to constitute a buildup substrate. FIG. 9 shows the cross-section of such a buildup substrate. The buildup substrate shown in FIG. 9 has the substrate 17 formed by a plurality of resin layers formed on the surface and the rear surface of the multilayer substrate 1. The substrate 17 has an inner layer wiring 19 and a via hole 18 formed thereon, which are connected to the surface wiring 2 formed on the surface or the rear surface of the multilayer substrate 1.

According to the above description, the current-carrying element 9 is connected to the ground electrode 14 if the current-carrying element 9 is the short stub type. However, the following case is also thinkable.

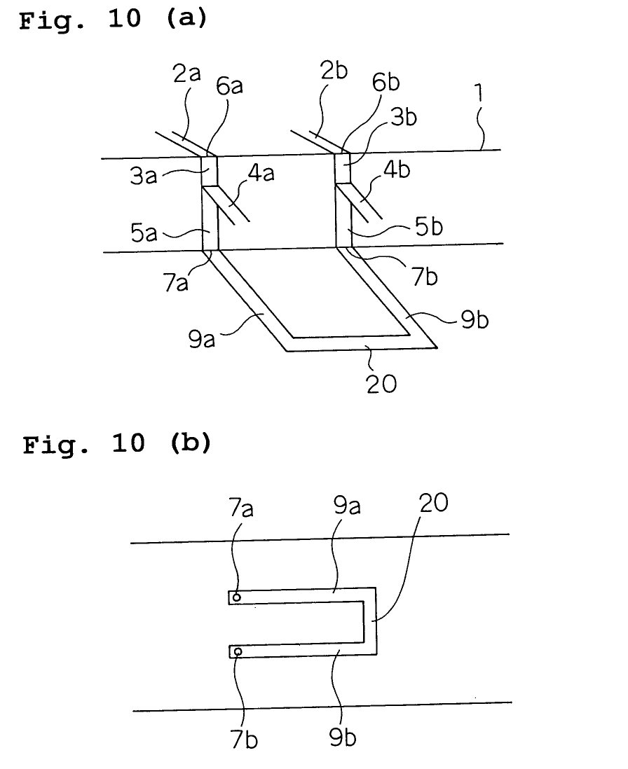

FIG. 10(a) shows an internal perspective view of a short-stub type printed circuit board in the case where a differential signal line is connected as the surface wiring to via holes 3a and 3b. FIG. 10(b) shows a plan view seeing the printed circuit board shown in FIG. 10(a) from the rear surface side thereof. Ends 6a and 6b of the via holes 3a and 3b have surface wirings 2a and 2b connected thereto, and have differential signals inputted thereto via the surface wirings 2a and 2b. To be more specific, the differential signals are inputted to the surface wirings 2a and 2b so that a phase of the signal inputted to the surface wiring 2a and the phase of the signal inputted to the surface wiring 2b become mutually opposite. And it is constituted so that the total of the electrical length (L1) of second portions 5a and 5b of the via holes 3a and 3b and the electrical length (L2) of current-carrying elements 9a and 9b connected to ends 7a and 7b of the via holes 3a and 3b satisfy (Formula 2) respectively. And the current-carrying elements 9a and 9b are mutually shorted at a connection portion 20. If the differential signals are inputted to the printed circuit board of such configuration, the connection portion 20 is virtually grounded, and the second portion 5a and current-carrying element 9a and the second portion 5b and current-carrying element 9b become equivalent to the state of being connected to the ground electrode 14 so as to operate as the short stubs respectively. Therefore, according to the printed circuit board shown in FIGS. 10, it is possible, without separately requiring the ground electrode, to implement the short-stub type printed circuit board in a compact form.

In the example shown in FIGS. 10, the via hole 3a according to the present invention is corresponding to the via hole according to the present invention, the via holes 3b is corresponding as an example to another via hole according to the present invention, the surface wiring 2a is corresponding to one of the differential signal lines according to the present invention, the surface wiring 2b is corresponding as an example to the other differential signal line according to the present invention, the end 6a is corresponding to the first end according to the present invention, the end 6b is corresponding as an example to one end of another via hole according to the present invention, the end 7a is corresponding to the second end according to the present invention, the end 7b is corresponding as an example to the other end of another via hole according to the present invention, the current-carrying element 9a is corresponding to the current-carrying element according to the present invention, and the current-carrying element 9b is corresponding as an example to another current-carrying element according to the present invention.

According to the above description, one inner layer wiring 4 existing in the multilayer substrate 1 is connected to the via hole 3. In the case where a number of inner layer wirings 4 exist and are connected to the via hole 3 respectively, however, the connection point closest to the end 7 of the connection points between the inner layer wirings 4 and the conductive part of the via hole 3 should be the connection point 8. In that case, it is also possible to obtain the same effect as described above.

The scope of this embodiment also includes the method of manufacturing the printed circuit board having a step of connecting the current-carrying element 9 to the end 7 having no surface wiring 2 connected thereto on the opposite side to the end 6 of the via hole 3 penetrating the multilayer substrate 1 and having the surface wiring 2 connected to the end 6 of the conductive part thereof, and a step of, determining the electrical length of the current-carrying element 9 so that the value of the impedance at the predetermined frequency is higher than the predetermined value on seeing the current-carrying element 9 side from the connection point 8 closest to the end 7, of the connection points between at least one inner layer wiring 4 connected to a portion other than the end 6 and the end 7 of the conductive part of the via hole 3 and formed inside the multilayer substrate 1 and the conductive part of the via hole 3, and wherein the predetermined value is the value of the impedance at the predetermined frequency on seeing the end 7 side from the connection point 8 in the case where the current-carrying element 9 does not exist.

### EXAMPLE 1

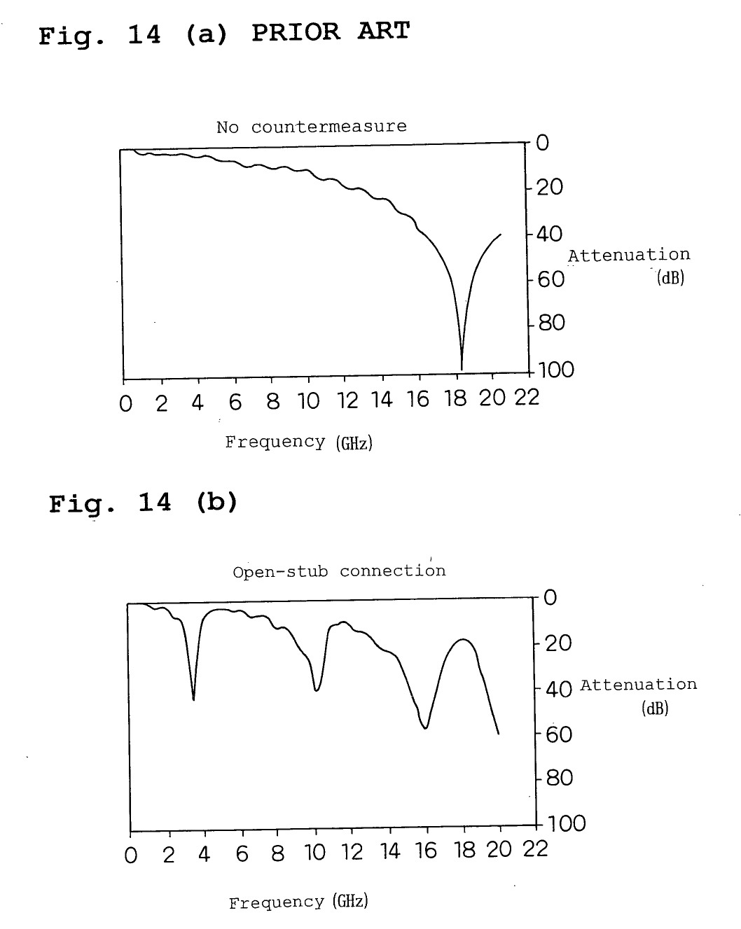

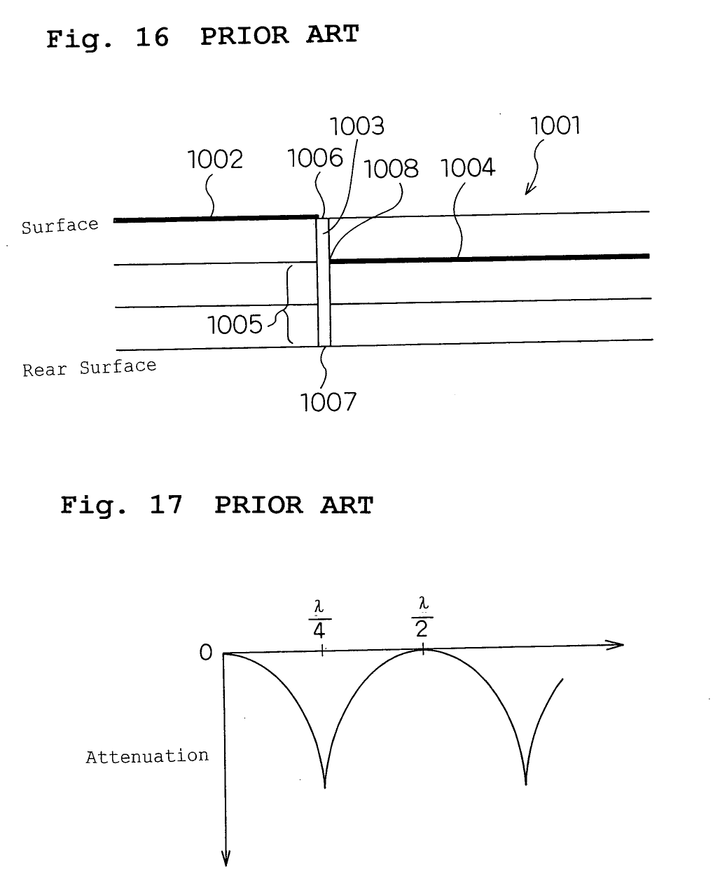

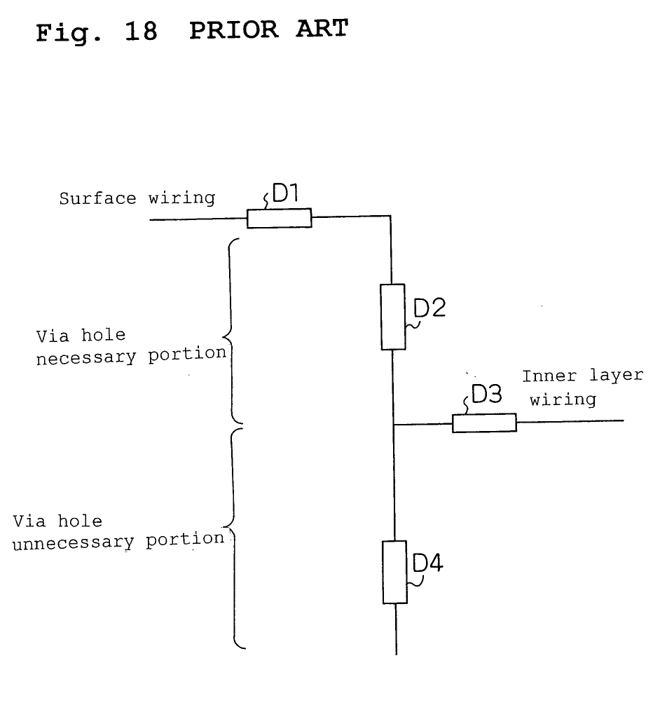

FIG. 14 shows a comparison between the case of using the current-carrying element 9 as the open stub and the case of using no current-carrying element 9. FIG. 14(a) shows a frequency characteristic of an attenuation of signal power conveyed from a surface wiring 1002 to an inner layer wiring 1004 on the printed circuit board of a past example shown in FIG. 16 in the case of using no current-carrying element 9. The attenuations of the desired frequencies at 5 GHz and 18 GHz are 5.5 dB and 98 dB respectively. FIG. 14(b) shows the frequency characteristic of the attenuation in the case of using the current-carrying element 9 shown in FIG. 1. The attenuations of the desired frequencies at 5 GHz and 18 GHz are 3.2 dB and 18 dB, showing improvement in the attenuation.

(Second Embodiment)

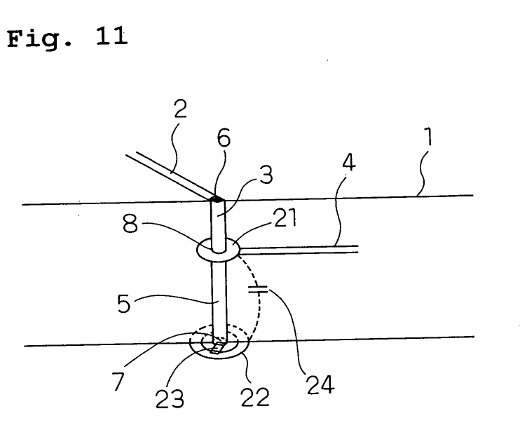

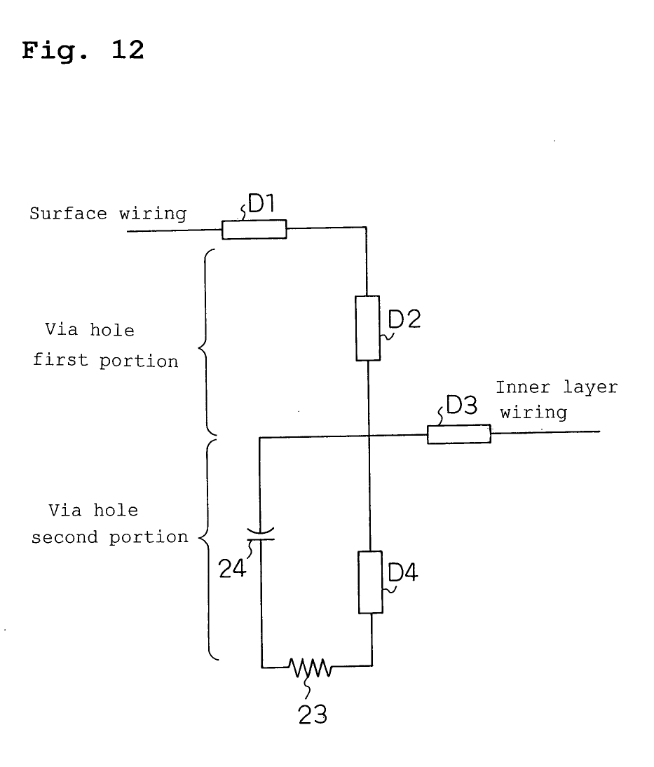

FIG. 11 shows an internal perspective view of the printed circuit board according to a second embodiment of the present invention.

First, the configuration of the printed circuit board according to the second embodiment will be described. The same components as those in the first embodiment will be given the same reference numerals and a description thereof will be omitted. As for the printed circuit board according to the second embodiment, one end of a chip resistor 23 as an example of the resistor of the present invention is connected to the end 7 of the conductive part of the via hole 3, and the other end of the chip resistor 23 is connected to a land pattern 22 as an example of a land formed on the rear surface of the multilayer substrate 1 of the present invention. An inner layer pattern 21 as an example of the land-like inner layer pattern of the present invention is formed on the connection point 8 between the inner layer wiring 4 and the via hole 3. The inner layer pattern 21 is the land inevitably formed on forming the via hole 3 on the multilayer substrate 1, which is enlarged. The land pattern 22 has almost the same size as the inner layer pattern 21, and is formed opposite the inner layer pattern 21.

As shown in FIG. 11, the inner layer pattern 21 and the land pattern 22 are placed on the upper end and lower end of the second portion 5 of the via hole 3 so that it is equivalent to having a capacitor 24 as an example of the capacitor of the present invention formed by the inner layer pattern 21 and the land pattern 22 as the electrodes and a part of the multilayer substrate 1 as a dielectric sandwiched between the inner layer pattern 21 and the land pattern 22. Thus, series circuits of the chip resistor 23 and capacitor 24 are connected in parallel to the second portion 5 of the via hole 3 so as to lower a Q value of a parasitic resonant circuit formed by the second portion 5 of the via hole 3. FIG. 12 shows the equivalent circuit of the printed circuit board constituted as above according to this embodiment.

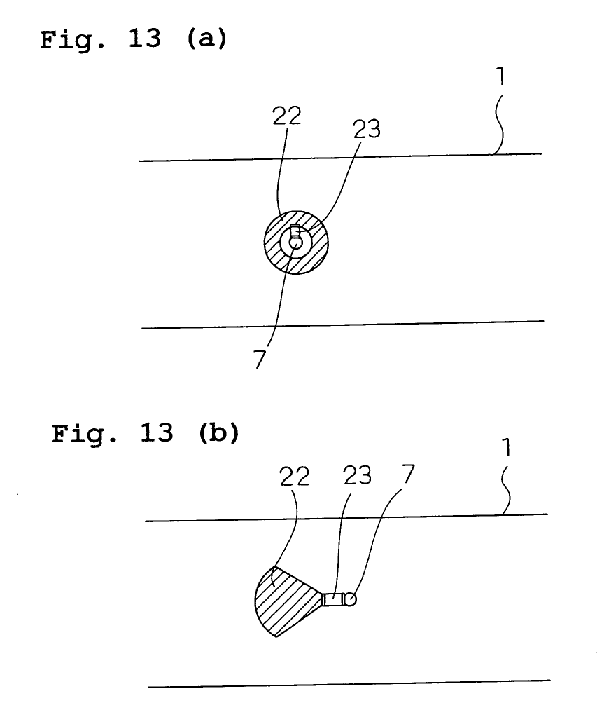

FIG. 13(a) shows a plan view seeing the printed circuit board shown in FIG. 11 from the rear surface. FIGS. 11 and 13A show the land pattern 22 in a circular shape, but it may be a sector as shown in FIG. 13(b) for instance. It may also be in any other shape such as a square. In that case, that is, if the land pattern 22 is in a sectorial shape for instance, the inner layer pattern 21 connected to the inner layer wiring 4 is also rendered sectorial. And the sectorial shape of the land pattern 22 on the rear surface and the sectorial shape of the inner layer pattern 21 are placed by sandwiching the part of the multilayer substrate 1 so as to face each other.

As described above, according to the printed circuit board of this embodiment, it is possible to lower a Q value of a parasitic resonant circuit formed by the second portion 5 of the via hole 3 so as to reduce the transmission loss of the signal.

According to the above description, one inner layer wiring 4 existing in the multilayer substrate 1 is connected to the via hole 3. In the case where a number of inner layer wirings 4 exist and are connected to the via hole 3 respectively, however, the connection point closest to the end 7 of the connection points between the inner layer wirings 4 and the conductive part of the via hole 3 should be the connection point 8. In that case, it is also possible to obtain the same effect as described above.

According to the above description, the capacitor 24 is formed by the inner layer pattern 21, the land pattern 22 and the part of the multilayer substrate 1 sandwiched between the inner layer pattern 21 and land pattern 22. However, it may also have the configuration wherein the inner layer pattern 21 of connecting the inner layer wiring 4 and the connection point 8 is not especially formed, but the capacitor 24 is constituted by a wiring pattern itself forming the inner layer wiring 4, the land pattern 22 and the part of the multilayer substrate 1 sandwiched between them.

The buildup substrate shown in FIG. 9 was described by using the example utilizing the printed circuit board of the first embodiment. There is also the thinkable case where the substrate 17 formed by at least one resin layer is formed on the surface or the rear surface of the printed circuit board of the second embodiment so as to constitute the buildup substrate.

The scope of this embodiment also includes the method of manufacturing the printed circuit board by connecting the series circuits of the chip resistor 23 and capacitor 24 between the end 7 having no surface wiring 2 connected thereto on the opposite side to the end 6 of the via hole 3 penetrating the multilayer substrate 1 and having the surface wiring 2 connected to the end 6 of the conductive part thereof and the connection point 8 closest to the end 7, of the connection points between at least one inner layer wiring 4 connected to a portion other than the end 6 and the end 7 of the conductive part of the via hole 3 and formed inside the multilayer substrate 1 and the conductive part of the via hole 3.

### EXAMPLE 2

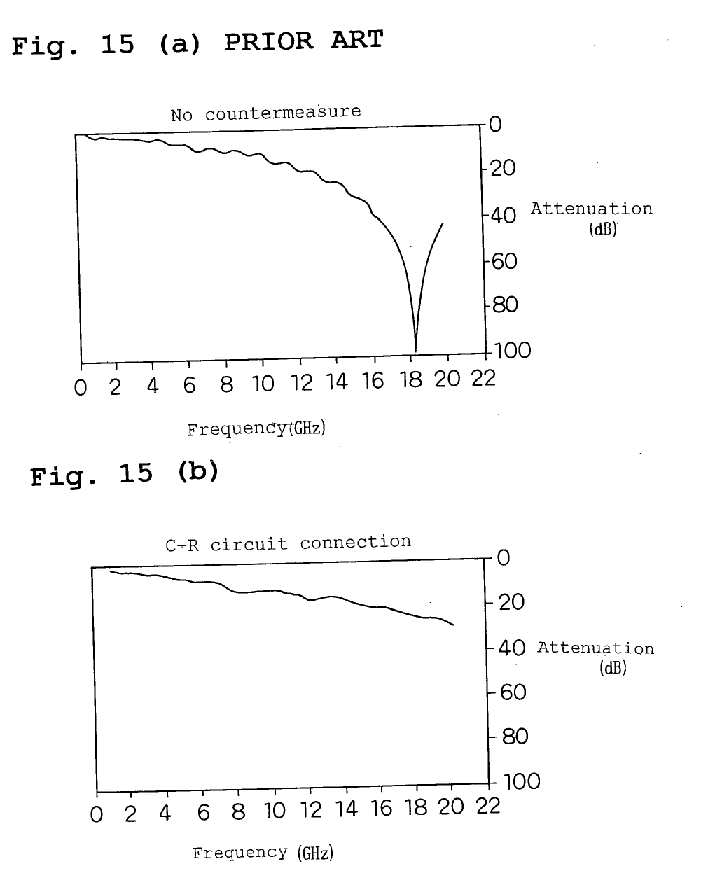

FIG. 15 shows a comparison between the case of using a C-R series circuit and the case of using no C-R series circuit. FIG. 15(a) shows the frequency characteristic of the attenuation of signal power conveyed from the surface wiring 1002 to the inner layer wiring 1004 on the printed circuit board of the past example shown in FIG. 16. The attenuation at the desired frequencies of 18 GHz is 98 dB. FIG. 15(b) shows the frequency characteristic of the attenuation of the signal power conveyed from the surface wiring 2 to the inner layer wiring 4 in the case of connecting the series circuits of the chip resistor 23 and capacitor 24 in parallel between the connection point 8 and the end 7. The attenuation at the desired frequency of 18 GHz is 23 dB, showing significant improvement in the attenuation.

According to the above description, the printed circuit board of the present invention has its surface side differentiated from its rear surface side. However, the differentiation is for convenience in description, and so the surface side and the rear surface side may be opposite as to the printed circuit board of the present invention.

It goes without saying that, although the multilayer substrate 1 indicated in the above description is illustrated as having three layers, it is not limited thereto but may have any number of layers.

It was described that the multilayer substrate 1 is the glass epoxy substrate. However, it may be constituted by a material other than the glass epoxy substrate. For instance, the multilayer substrate 1 may be a ceramic substrate. In that case, the conductive part of the via hole 3 should be formed by including the second portion 5 rather than forming only the first portion and connecting the current-carrying element 9 to the end 7 of the via hole so as to manufacture the printed circuit board more easily. Then, it is possible to obtain the same effect as described above.

The scope of the present invention also includes an electronic device having the printed circuit board according to the first or second embodiment and electronic components mounted on the surface of or inside the printed circuit board. In the above examples, the cases of 5 GHz and 18 GHz are cited as the predetermined or desired frequencies of the present invention. However, they are just the examples and not indicating any limitation. For instance, they may be the frequencies used on a transmitter or a receiver and may also be the frequencies used on another electronic device. Even in such cases, it is possible to obtain the same effect.

It is possible, according to the printed circuit board, buildup substrate and method of manufacturing the printed circuit board of the present invention, to curb the transmission loss thereof at the desired frequency so as to be useful for the printed circuit board, buildup substrate and so on.

What is claimed is:

1. A printed circuit board having:
a multilayer substrate;
a via hole penetrating said multilayer substrate;
a surface wiring wired on the surface of said multilayer substrate and connected to a first end which is one end of said via hole;
at least one inner layer wiring formed inside said multilayer substrate and connected to a portion other than upper and lower ends of a conductive part of said via hole; and
a current-carrying element connected to a second end having no said surface wiring connected thereto on an opposite side to said first end of the conductive part of said via hole; and wherein:
said current-carrying element has an electrical length by which a value of an impedance at a predetermined frequency is larger than a predetermined value on seeing said current-carrying element side from a first connection point closest to said second end, of the connection points between said inner layer wiring and the conductive part of said via hole; and
said predetermined value is the value of the impedance at the predetermined frequency on seeing said second end side from said first connection point in the case where said current-carrying element does not exist.

2. The printed circuit board according to claim 1, wherein the total of the electrical length from said first connection point to said second end and the electrical length of said current-carrying element is substantially n/2 times (n is a natural number) a wavelength corresponding to said predetermined frequency, and the end of said current-carrying element is open.

3. The printed circuit board according to claim 1, wherein the total of the electrical length from said first connection point to said second end and the electrical length of said current-carrying element is substantially (2n−1)/4 times (n is a natural number) a wavelength corresponding to said predetermined frequency, and the end of said current-carrying element is grounded.

4. The printed circuit board according to any one of claims 1 to 3, wherein a part of said current-carrying element is formed by a chip inductor.

5. The printed circuit board according to any one of claims 1 to 3, wherein a part of said current-carrying element is formed by at least one via hole.

6. The printed circuit board according to any one of claims 1 to 3, wherein a shape of said current-carrying element is substantially a sector.

7. The printed circuit board according to claim 1, wherein said current-carrying element is formed between predetermined layers between said first connection point and said second end and is connected to the conductive part of said via hole instead of being connected to said second end.

8. The printed circuit board according to claim 1, further having another via hole penetrating said multilayer substrate different from said via hole; and wherein:
said surface wiring is a differential signal line, and one end of said differential signal line is connected to the first end of said via hole and the other end of said differential signal line is connected to one end of said other via hole;
at least one inner layer wiring is connected to a portion other than upper and lower ends of the conductive part of said other via hole;
a current-carrying element other than said current-carrying element is connected to the other end of said other via hole;
of the conductive part of said via hole, the total of the electrical length from said first connection point to said second end and the electrical length of said current-carrying element is substantially (2n−1)/4 times (n is a natural number) a wavelength corresponding to said predetermined frequency;
of the conductive part of said other via hole, the total of the electrical length from the connection point closest to said other end to said other end of the connection points to said inner layer wiring and the electrical length of said other current-carrying element is substantially (2n−1)/4 times (n is a natural number) the wavelength corresponding to said predetermined frequency; and
the end of said current-carrying element and the end of said other current-carrying element are mutually connected.

9. A printed circuit board having:
a multilayer substrate;
a via hole penetrating said multilayer substrate;
a surface wiring wired on the surface of said multilayer substrate and connected to a first end which is one end of said via hole;
at least one inner layer wiring formed inside said multilayer substrate and connected to a portion other than upper and lower ends of a conductive part of said via hole; and
a series circuit of a resistor and a capacitor, and wherein:
said series circuit is connected, of the conductive part of said via hole, between a second end having no said surface wiring connected thereto on an opposite side to said first end and a first connection point closest to said second end, of the connection points between said inner layer wiring and the conductive part of said via hole.

10. The printed circuit board according to claim 9, wherein said resistor is a chip resistor connected to said second end;
said capacitor is formed by said inner layer wiring or inner layer pattern and a land as electrodes and a part of said multilayer substrate as a dielectric; and
said inner layer wiring or inner layer pattern is connected to said first connection point, said land is formed on a surface on which said second end exists and is connected to said chip resistor, and a part of said multilayer substrate is formed by being sandwiched between said inner layer wiring or inner layer pattern and said land.

11. A buildup substrate having the printed circuit board according to claim 1 and a substrate layer of at least one layer formed on said printed circuit board.

12. A method of manufacturing a printed circuit board having:
a step of connecting a current-carrying element to a second end having no surface wiring connected thereto on an opposite side to a first end of a via hole penetrating a multilayer substrate and having a surface wiring connected to said first end of a conductive part thereof; and
a step of determining an electrical length of said current-carrying element so that a value of an impedance at a predetermined frequency on seeing said current-carrying element side from a first connection point closest to said second end, of connection points between at least one inner layer wiring connected to a portion other than said first end and said second end of the conductive part of said via hole and formed inside said multilayer substrate and the conductive part of said via hole, is higher than a predetermined value, and wherein:
said predetermined value is the value of the impedance at said predetermined frequency on seeing said second end side from said first connection point in the case where said current-carrying element does not exist.

13. A method of manufacturing a printed circuit board, wherein a series circuit of a resistance and a capacitor is connected between a second end having no surface wiring connected thereto on an opposite side to a first end of a via hole penetrating a multilayer substrate and having a surface wiring connected to said first end of a conductive part thereof and a first connection point closest to said second end, of connection points between at least one inner layer wiring connected to a portion other than said first end and said second end of the conductive parts of said via hole and formed inside said multilayer substrate and the conductive part of said via hole.

14. An electronic device having the printed circuit board according to claim 1 and electronic components mounted on the surface of or inside said printed circuit board.
